(19) United States
(12) Patent Application Publication
(10) Pub. No.: US 2005/0174014 A1
(43) Pub. Date: Aug. 11, 2005

(54) Adjustable filter and method for adjusting the frequency

(76) Inventors: Christian Korden, Deutschlandsberg (AT); Werner Ruile, Munchen (DE)

Correspondence Address: SCHIFF HARDIN, LLP;PATENT DEPARTMENT, 6600 SEARS TOWER, CHICAGO, IL, 60606-6473, US

(21) Appl. No.: 10/517,092

(22) PCT Filed: May 7, 2003
(86) PCT No.: PCT/DE03/01466

(30) Foreign Application Priority Data
Jun. 6, 2002 (DE) 102 25 201.7

(51) Int. Cl. H02N 2/00; H01L 41/04; H01L 41/08; H01L 41/18

(52) U.S. Cl. 310/322

(57) ABSTRACT

In a component operating with acoustic waves, a GDE layer is provided in close mechanical contact with a piezoelectric excitation layer which can significantly change their rigidity under a mechanical warping and the sound propagation speed. The degree of the material expansion or, respectively, compression can be adjusted by applying a voltage to two control voltage electrodes and a piezoelectric tuning layer.

### BACKGROUND OF THE INVENTION

The invention concerns a tunable component operating with acoustic waves, in particular a filter as well as a method for frequency tuning.

By components operating with acoustic waves, essentially what are understood are SAW components (surface wave components), FBAR resonators (Thin Film Bulk Acoustic Wave resonator) and components operating with surface-proximal waves. Such components can, for example, be used as delay lines, resonators or as ID tags. However, these components have great importance in particular as filters in wireless communication systems. These systems operate worldwide with regionally different transmission standards which, among other things, are characterized by different frequency positions for the transmission and reception bands as well as by different bandwidths. Since the usability of a telecommunication end device which listens to only one standard is thus regionally limited, such end devices that listen to more than one standard are desirable. Therefore multi-band end devices or, respectively, combined multi-band/multi-mode end devices already exist today. Additionally, these normally comprises a separate filter for each frequency band and can switch back and forth between different transmission and reception systems in this manner. However, due to the plurality of filters necessary for this and further necessary components, these end devices are significantly more expensive and heavier than before, and moreover run opposite to the trend of increasing miniaturization of mobile end devices.

It has already been proposed to use switchable filters that can switch over between different operating frequencies for a multi-band/multi-mode end device in order to therewith cover different frequency bands with a single filter. Additionally, for filters in SAW technology it is known to attach on a substrate different filter elements or different electrode sets which can be switched between one set to another. However, here the switches are always afflicted with electrical losses and the additional chip area for the further electrode sets which this technology requires are disadvantageous. Moreover, in this manner it is only possible to select or, respectively, to switch between concretely predetermined switch states.

Furthermore, it has already been proposed to achieved analog tunable filter in order to design a filter for different frequencies. However, conventional SAW filters are known for their frequency stability and therefore are not tunable, or only tunable within very narrow limits. For tuning it is known to connect a variable capacitor in parallel to the filter, to use a variable ferroelectric material, to use a variable-conductivity layer or to give variable loads to individual filter elements. The tunable bandwidth, which is achievable therewith and, thus the maximum variable frequency range for such filters, is however rather low and not sufficient to be able to operate a SAW filter via frequency tuning in different frequency bands.

A further filter technology operating with acoustic waves is the FBAR- or BAW-filter technology, in which a bandpass filter can be realized via interconnection of various single-port resonators designed with FBAR technology. Here as well it is possible for a filter to be switchable between various frequencies to provide different filter elements such as, for example, different electrodes or completely different resonators or filters. It was also already proposed for FBAR filters to provide parallel variable capacitors, variable ferroelectric materials, variably conductive layers or variable loads for individual filter elements in order to thereby realize switchable or tunable filters. Just like with the SAW technique, the frequencies can also be tuned within only very narrow limits in this manner.

In U.S. Pat. No. 5,959,388, a SAW component is specified which can be tuned with a magnetic field. A piezoelectric layer on which the SAW component is realized is additionally mounted on a magnetostrictive material. Under the influence of an external magnetic field, a mechanical warping that leads to a change of the speed of the surface wave is generated in the magnetostrictive layer. The frequency of the SAW component can be shifted in this manner. Since the magnetic field is generated with a coil, this represents an elaborate construction that can only be controlled with difficulty, and is particularly unsuitable for mobile end devices due to the energetic losses.

Moreover, in the German patent application 102 08 169.7, a solution for frequency tuning is described in which the regulation of the frequency position is reached in a simple manner by means of two control electrodes via which the permeability of a hybrid permeability element is influenced. The hybrid permeability element is comprised of at least a composite of a piezoelectric control layer and a magnetostrictive layer. The magnetic field and therewith the elastic properties of the magnetosensitive layer are influenced with a control voltage applied to the control electrodes, which has an effect on the propagation speed of an acoustic wave in this material. The frequency position of the component fashioned in the piezoelectric layer over the magnetosensitive layer is thereby influenced.

A significant disadvantage of the last cited method is that the permeability element used for modulation of the magnetic field must be subsequently connected with the actual filter element as a separate component part or even be integrated into the filter housing. A significant additional effort occurs that represents a significant cost factor with regard to the housing technology.

### SUMMARY OF THE INVENTION

It is the object of the present invention to specify a component operating with acoustic waves which can be simply tuned in its frequency position and which is suitable for production of filters operating in various frequency bands.

The invention specifies a component which exhibits a simple multilayer design and which can be tuned in its frequency position in a simple manner.

The tuning of the frequency position is effected via a varying voltage—the control voltage—which is applied to a piezoelectric layer—the tuning layer—and, due to an inverse piezoelectric effect, effects mechanical expansion or compression of the piezomaterial. The mechanical warpings are furthermore immediately (in contrast to the solutions previously known with tunable filters without introduction of a magnetic field in the component or externally controlled) transferred to an abutting thin GDE layer. This is in close mechanical contact with a piezoelectric excitation layer in which the electrode structures which represent component structures are realized. The elastic properties in the GDE layer are determined via the mechanical warpings or, respectively, corresponding changed with varying control voltage.

GDE materials (Giant Delta E) are materials that exhibit an extraordinarily high change of the elasticity modulus under a mechanical warping. A series of such materials made from the most different material classes has recently been made known.

A large rigidity change via mechanical warpings is, for example, achieved with specific metallic glasses, what are known as metglasses, that are primarily comprised of the metals iron, nickel and cobalt. Thus, for example, metglasses of the composition Fe₈₁Si_{3.5}B_{13.5}C₂, FeCuNbSiB, Fe₄₀Ni₄₀P₁₄B₆, Fe₅₅Co₃₀B₁₅ or Fe₈₀ with Si and Cr exhibit a strong delta E effect. Such metglasses are, for example, known under the brand names VITROVAC® 4040 of Vakuumschmelze or under the designation Metglas® 2605 SC (Fe₈₁Si_{3.5}B_{13.5}C₂).

Multilayer systems with amorphous structure based on mixed metal oxides are also suitable, for example the two-layer system Fe₅₀Co₅₀/Co₅₀B₂₀.

Binary and pseudobinary systems made from rare earth metals such as TbFe₂ or Tb_{0.3}Dy_{0.7}Fe₂ are also possible.

One-crystal systems such as Terfenol also show a strong ΔE effect in the compound TbₓDy₁₋ₓFe_{y} with 0.27≦x≦0.3 and 1.9≦y≦1.95 or F₁₄Nd₂B.

A further substance class with high ΔE effect is the phosphate RPO₄ of rare earths. R thereby stands for the rare earths from Tb through Y, for example for TbPO₄, TmPO₄ and DyPO₄. These compounds exhibit a polycrystalline structure, however can also be used in tetragonal one-crystal form.

Dependent on the material selected for the GDE layer, its elasticity modulus can be changed up to a factor of more than 2. The speed of the surface wave, which is dependent on the root of the elasticity modulus, can correspondingly be changed by more than 30%, which corresponds to the change of the frequency position of the component that is proportional to the speed of the surface wave.

All materials cited above change their elastic properties by up to 100% upon application of a magnetic field without therefore operating in proximity to a phase transition. As a consequence of this, the change of the properties is also proportional to the applied magnetic field, such that a good regulation of these properties via a magnetic field is possible.

The inventive component can be fashioned as a SAW component on the (thin) piezoelectric excitation layer. The electrode structures and all remaining component structures, for example interdigital transducer, reflectors as well as electrical leads and connections are arranged on this piezoelectric layer. The GDE layer is arranged below the piezoelectric layer. The change of the rigidity of a GDE material as a result of mechanical warpings in turn causes a change of the propagation speed of the surface wave. Since the penetration depth of the SAW during the propagation approximately corresponds to a half-wavelength λ, the thickness of the piezoelectric layer is selected correspondingly thinner than λ/2 in order to ensure the partial propagation of the wave within the GDE layer and therewith the desired effect.

Since the GDE layers moreover exhibit magnetostrictive properties, in the invention it is undesirable that the acoustic wave generated in the component has a reaction on the GDE layer that would lead to a non-linearity of the component. Therefore the GDE layers are selected such that their maximum switching frequency and, thus, the response to a mechanical effect via the inverse magnetostrictive effect due to the acoustic wave, lies far below the frequency range of the acoustic wave in which the component operates. This has the result that the acoustic wave generates no feedback whatsoever in the operating frequency of the component via the magnetostrictive effect in the GDE layer. This requirement is fulfilled for all layers used in the inventive multilayer design. Nevertheless, the components can be switched over with a sufficient speed. The inertia of the magnetostrictive effect still allows switching frequency in the kilohertz range, which corresponds to switching times of less than 1 ms.

An inventive component can also be fashioned as a FBAR resonator. Such a component operating with volume waves comprises a piezoelectric layer that is arranged between two electrode layers. One of the electrode layers, in particular the lower electrode layer, can inventively be fashioned as a GDE layer. This is inasmuch possible in a simple manner since most of the GDE materials exhibit a sufficient electrical conductivity. Otherwise a thin, highly-conductive layer is provided as an additional electrode layer. It is also possible to fashion the cited GDE layer as an upper electrode layer for the FBAR resonator. A further possibility is to produce both electrode layers from a GDE material. It is also possible to fashion the GDE layer as a layer additional to the electrode layers, whereby the GDE layer can be arranged above or below the electrode layers or directly adjacent to the piezoelectric layer.

Given the execution as an FBAR resonator, the entire component is preferably built on a substrate on which the individual layers are generated or, respectively, are deposited atop one another individually and in succession. Glass or semiconductor such as, for example, silicon serve as substrate materials. Further suitable substrate materials are ceramic, metal, plastics as well as other materials with corresponding mechanical properties on which the layers necessary for the component can be deposited. Multilayer superstructures made from at least two different layers are also possible. The substrate is mechanically stable and preferably adapted in terms of coefficients of expansion to the layer structure applied atop them, in order to minimize warping via different thermic expansion in the layers of the component sensitive to dimensional changes.

Given the formation of the component as an FBAR resonator (BAW resonator, BAW stands for Bulk Acoustic Wave), various design variants exist that can differ with regard to the layer sequence in the component. For example, for the acoustic decoupling of the FBAR resonator from the substrate, an acoustic mirror can be provided that reflects the acoustic wave in the resonator such that no losses are created via radiation of the wave in the substrate. Such an acoustic mirror can be produced in a simple manner from at least two, however mostly four or more λ/4 layers whose thickness is a quarter (or an odd-numbered multiple of λ/4, i.e. (2n+1)*λ/4, whereby n is a whole number, n=0, 1, 2, . . . ) of the wavelength of the acoustic wave capable of propagating in the material. Different materials with different acoustic impedance are used for these λ/4 layers, whereby the reflection coefficient of the acoustic mirror rises with impedance difference growing larger between the materials of the mirror layers. An acoustic mirror can, for example, be formed of alternating layers of tungsten and silicon oxide, silicon and silicon oxide, molybdenum and silicon oxide or other layer pairs that are characterized by sufficient differences with regard to their acoustic impedance and that can be alternately, controllably deposited over one another in thin layer techniques. The number of the layer pairs necessary for a sufficient reflection coefficient of the acoustic mirror is dependent on the material selection, since different layer pairs exhibit different reflection coefficients.

The GDE layer can be a partial layer of the acoustic mirror. The electrode layer computer network can also be part of the acoustic mirror. However, it is also possible to fashion the acoustic mirror in addition to both cited layers.

A further embodiment of FBAR resonators uses the high impedance difference between solids and air in order to achieve a sufficient reflection coefficient for the acoustic wave at the boundary surface. Such FBAR resonators are therefore fashioned over an air gap, for example self-supporting or over an additional thin membrane layer. The support points of the FBAR resonator on the substrate are selected such that they are laterally displaced against the active resonator volume, which in particular is defined by the electrode surface for the FBAR resonator.

To tune the inventive component, a dimension change (that is transferred to the GDE layer fashioned as a thin layer) of the piezoelectric control layer is generated via the control voltage to be applied to control electrodes. Due to its conductivity, the GDE layer can serve as one of the control electrodes for the piezoelectric layer. The second control electrode, for example an aluminum layer, is applied on the piezoelectric tuning layer opposite the GDE layer.

To shield the component against external electrical and most notably magnetic fields, a metallic covering, shell, a metallic housing or the like, in particular Mu-metal, is suitable.

Due to the good tuning capability with regard to the operating frequency of the component, this is in particular suitable as a filter and in particular as a front end filter for a wireless communication end device, for example a mobile telephone. An inventive component as a front end filter can be tuned to a series of different frequency bands due to the large tuning range, up to 30% relative to the center frequency of the filter. Thus, it is possible with a single inventive filter to be operating in different transmission and reception bands. While until now a plurality of filters were necessary for an operation in multiple bands, now a single inventive filter is sufficient. With 2 or 3 filters, even the entire frequency spectrum of the mobile frequencies, which are typical today, could be covered in this manner.

Inventive components fashioned as FBAR resonators still do not themselves represent filters, but rather act first in an interconnection of a plurality of components, for example in a branch circuit as a bandpass filter. With the invention it is now possible to shift all inventive FBAR resonators which are interconnected into a bandpass filter and with a common tuning layer with regard to their frequency and with regard to the center frequency of the passband. However, it is also possible to provide two or more tuning layers in a component and thus to differently influence a plurality of filter components. If a bandpass filter is realized via inventive FBAR resonators, the resonators can thus be arranged into groups such that a different effect of the resonators with regard to their center frequency is arrived at with the aid of a plurality of tuning layers. In a bandpass filter in branching technology, it is for example possible to treat or, respectively, to influence resonators arranged in the serial branch differently than the resonators arranged in the parallel branch. In this manner it is possible to influence the bandwidth of the entire filter. Given an increasing separation of the middle frequencies between the resonators in the parallel arm and in the serial arm, the bandwidth of the filter is increased.

The duplexer separations in a duplexer which is produced from inventive components can also be affected with the same method. If one of the two individual filters (comprised of inventive transmission and reception filters) of the duplexer is shifted in terms of its center frequency against the corresponding other filter with the aid of a tuning layer, the band separation is increased or reduced. Via independent influence of transmission and reception filters with the aid of separate tuning layers and different adjustable control voltages, it is possible to vary the duplexer both in the band separation and in the frequency position by more than 30% within the scope of the inventive bandwidth.

In the following the invention is explained in detail using exemplary embodiments and associated schematized (and therefore not to scale) Figures.

### BRIEF DESCRIPTION OF THE DRAWINGS

FIG. 1 shows an inventive component fashioned as an FBAR resonator in schematic cross-section;

FIG. 2 shows a further inventive component fashioned as an FBAR resonator in schematic cross-section;

FIG. 3 shows an inventive component fashioned as a SAW component in schematic cross-section; and

FIGS. 4 and 5 show further inventive components fashioned as a SAW component in schematic cross-section.

### DESCRIPTION OF THE PREFERRED EMBODIMENTS

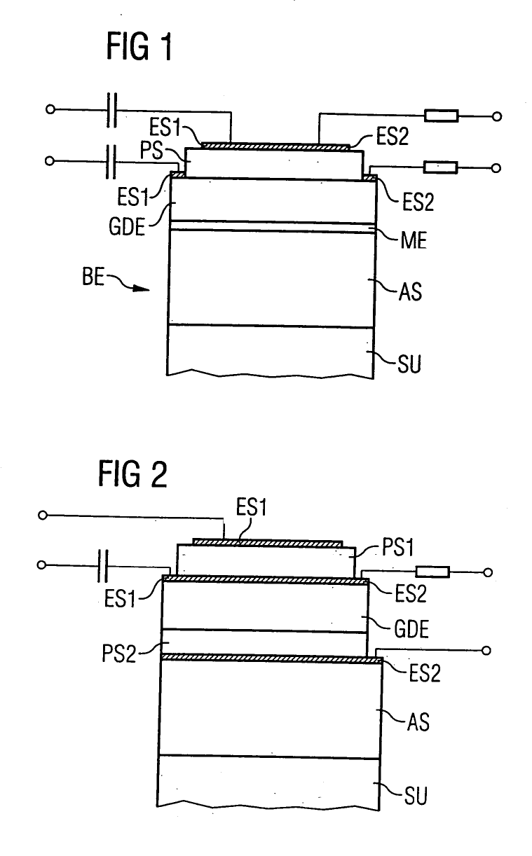

General features of the invention are explained in FIG. 1 using a schematic cross-section representation of an inventive BAW component (Bulk Acoustic Wave component).

The component BE is generated on a substrate SU as a multilayer component. It comprises a GDE layer GDE over which a piezoelectric layer PS is fashioned in close contact, which piezoelectric layer PS is provided on the one hand with a pair of HF electrodes ES1 to excite an acoustic volume wave and on the other hand with a pair of control voltage electrodes ES2. In the advantageous embodiment shown in FIG. 1, the top electrode at the same time represents both one of the HF electrodes and one of the control voltage electrodes ES2. The second HF electrode or, respectively, the second control voltage electrode ES2 is arranged next to the piezoelectric layer PS on the GDE layer.

In a further embodiment, the second HF electrode ES1 can be arranged below the piezoelectric layer PS. The second control voltage electrode of the electrode pair ES2 can lie either above or below the GDE layer GDE as a thin metal layer. The latter possibility is indicated in FIG. 1 by the metal layer ME to be alternatively provided. A further possibility is that the GDE layer replaces one of the HF electrodes or the control voltage electrodes. The control voltage electrodes can furthermore be arranged transverse to the piezoelectric layer.

The thickness of piezoelectric layer PS and GDE layer GDE are selected so that both layers lie in the penetration range of the acoustic wave.

The thickness ratio of piezoelectric layer PS to GDE layer GDE in the range of the penetration depth is another adjustable parameter for the inventive component. The greater the proportion of the GDE layer within the penetration depth, the greater the tuning range via which the operating frequency or, respectively, center frequency of the filter can be shifted. In contrast to this, a greater proportion of piezoelectric layer PS within the penetration depth increases the coupling and the bandwidth of the filter. Dependent on the desired properties of the component, the ratio is adjusted so that either a high coupling or a high tuning capability or a suitable optimization with regard to both properties is attained.

The acoustically active part of the component can be separated from the substrate SU via an acoustic mirror AS that provides for a hundred-percent reflection of the acoustic wave back into the acoustically active part of the component.

A further possibility is that the GDE layer represents a partial layer of the acoustic mirror AS. It is thereby also important here that the GDE layer lies in the penetration depth of the acoustic wave, so that in this embodiment the GDE layer is an upper partial layer of the acoustic mirror. A better tuning capability is thus achieved via a GDE layer.

It is also possible that either the lower control or HF electrode layer represents a partial layer of the acoustic mirror AS.

The varying voltage (control voltage) applied to the control electrodes is used for frequency tuning of the filter. In the exemplary embodiment of FIG. 1, the cited piezoelectric layer PS assumes a double function as an excitation layer to excite acoustic volume waves and as a tunable layer to generate a mechanical warping which is transferred to the GDE layer and causes a change of the material rigidity. The latter in turn influences the propagation speed of the acoustic wave and therewith the center frequency of the filter.

FIG. 2 shows the cross-section of a further advantageous embodiment of a tunable BAW component. The piezoelectric excitation layer PS1 lies between two HF electrodes ES1. The lower of these electrodes ES1 simultaneously represents a control voltage electrode ES2. Arranged under this is a GDE layer GDE that, in a further possible embodiment, can replace the last mentioned electrode in the event that the GDE layer is electrically conductive. The piezoelectric tuning layer PS2 lies between the GDE layer and the lower of the control voltage electrodes ES2.

The invention is explained in FIG. 3 for a SAW component using a schematic cross-section representation.

The component BE is generated as a multilayer component on a substrate. It comprises a GDE layer GDE over which a piezoelectric layer PS is fashioned in close contact. The component structures (electrode structures) ES1 are fashioned on the surface of the piezoelectric layer PS, for example as aluminum metallizations. The acoustic waves generated by the electrode structures ES1, for example by interdigital transducers, have a penetration depth of approximately a half-wavelength into the multilayer structure. The thickness of piezoelectric layer PS and GDE layer GDE are selected such that both layers lie in the penetration region of the acoustic wave.

A first control voltage electrode ES2 is arranged on the top side of the piezoelectric layer PS, which bears the acoustic structures such as, for example, interdigital transducers and reflectors. The electrically-conductive GDE layer GDE serves as a second control electrode ES2 in this exemplary embodiment.

The second control electrode can moreover be arranged above or below the GDE layer as an additional metal layer.

In the exemplary embodiment shown in FIG. 3, the piezoelectric layer PS serves both to excite acoustic surface waves and to control elastic properties of the GDE layer GDE lying thereunder by means of mechanical warpings that occur as a result of the inverse piezoelectric effect upon application of varying control voltage.

Using a schematic cross-section, FIG. 4 shows a further example of an inventive SAW component, whereby the GDE layer GDE is arranged between the piezoelectric excitation layer PS1 and the piezoelectric tuning layer PS2. A control voltage electrode ES2 lies below the tuning layer PS2. The second control electrode ES2 can be fashioned either as a GDE layer or as an additional metal layer above or below the GDE layer GDE.

In a further exemplary embodiment, a tunable SAW component without carrier substrate is shown in FIG. 5. The acoustic structures such as, for example, interdigital transducers or reflectors are located on the top side of the piezoelectric excitation layer PS1. The GDE layer GDE is arranged between the excitation layer PS1 and the piezoelectric tuning layer PS2. The latter is provided on both sides with control voltage electrodes ES2.

A further variation possibility is to fashion the upper control voltage electrode ES2 as a GDE layer.

For reasons of clarity, the invention has been shown using only a few exemplary embodiments, however, the invention is not limited to these. Further variation possibilities result from further relative arrangements of piezoelectric tuning layer, GDE layer and piezoelectric excitation layer different from the shown embodiments. Variations are also possible with regard to the electrode structures determining the type of the component and also with regard to the materials and dimensions used. Also not shown are measures to shield the inventive component, in particular shieldings made from Mu-metal.

The inventive component can moreover be comprised of a plurality of partial filter structures. The partial filter structures can be filters independent of one another, and can together form a diplexer which represents a frequency diplexer connected with an antenna. The partial filter structures can also together form a duplexer, whereby the partial filter structures respectively represent a transmission or reception filter. Each of the filter components or, respectively, the partial filter structures is thereby combined with a separate tuning layer, such that a tuning of the partial filter structures independent of one another is possible. For a diplexer, this means to raise or to lower the frequency separation of both frequency ranges to be separated from one another. In a duplexer, the duplexer separation can be adjusted in this manner. However, it is also possible to interconnect both partial filter structures into a single filter via serial or parallel circuiting. If, for example, identical partial filter structures are used, via independent tuning of individual or both partial filter structures their center frequencies can be shifted opposite to one another, so that the bandwidth of the overall filter changes. The partial filter structures can be individual filter traces of a SAW filter. The partial filter structures can, however, also be individual or groups of FBAR resonators within a ladder-type arrangement. The ladder-type arrangement can be formed of FBAR resonators or of single-port SAW resonators.

Moreover possible structures are a lattice-type arrangement of a plurality of SAW or FBAR resonators, a filter arrangement made from stacked SAW or FBAR resonators, what is known as the stacked-crystal filter (SCF) filter arrangement, or a filter arrangement made from coupled resonators: coupled-resonator filter (CRF) filter arrangement. A filter arrangement can also be formed by arbitrary combinations of the cited filter arrangements.

The mechanical carrier substrate (SU) can have a multilayer structure with integrated circuit elements. By a passive or active circuit element, what is understood is an inductor, a capacitor, a delay line, a resistor, a diode or a transistor. The cited circuit elements are advantageously fashioned as conductor paths or arbitrarily shaped metal surfaces between the individual layers of the carrier substrate or as vertical feedthroughs in the carrier substrate.

Moreover, discrete passive or active components or chip components (for example SAW components, microwave ceramic filters, LC chip filters, microstrip filters) can be arranged on the top side of the carrier substrate. These chip components can be contained by a common housing. It is possible that each individual chip component is separately housed.

Both circuit elements integrated into the carrier substrate and circuit elements arranged on the top side of the carrier substrate can form a part of an adaptation circuit, an antenna switch, a diode switch, a high-pass filter, a low-pass filter, a bandpass filter, a band elimination filter, a power amplifier, a diplexer, a duplexer, a coupler, a direction coupler, a balun, a mixer or a storage element.

An adaptation circuit in the inventive component part can be tunable. One part of the integrated adaptation circuit can, for example, be fashioned as one or more conductor traces on the top side of the carrier substrate for later fine adaptation.

An inventive component part can comprise both at least one symmetrical input or, respectively, output and at least one unsymmetrical input or, respectively, output.

A multilayered carrier substrate can contain layers made from multilayer ceramic, silicon or organic materials (for example plastics, laminates).

Both the chip components arranged on the top side of the carrier substrate and the discrete, passive or active components arranged on the top side of the carrier substrate can be SMD components (Surface Mounted Design components).

1-30. (canceled)

31. An electronic component operating with acoustic waves, with a multilayer structure, said component comprising:
at least one GDE layer;
at least one piezoelectric layer located in close contact with the GDE layer;
a piezoelectric excitation portion having HF electrodes to excite acoustic waves; and
a piezoelectric tuning portion with control voltage electrodes to change the elasticity modulus of the GDE material directly via a mechanical warping or the combination of the tuning layer and the GDE layer, the excitation portion and tuning portion being realized via the at least one piezoelectric layer.

32. An electronic component according to claim 31, which has at least one bulk acoustic wave resonator, wherein the piezoelectric excitation layer is a component part of said resonator.

33. An electronic component according to claim 32, which includes an acoustic reflector in which a partial layer of the acoustic reflector is executed as one of an electrode layer and a GDE layer.

34. An electronic component according to claim 32, in which electrodes are provided that serve both as HF electrodes to excite bulk acoustic waves and as control voltage electrodes to change the elasticity modulus of the GDE material and for frequency tuning of the bulk acoustic wave resonator.

35. An electronic component according to claim 31, which includes at least one surface wave component so that the excitation portion forms a piezoelectric substrate of the component.

36. An electronic component according to claim 35, in which one of the control voltage electrodes is arranged on the surface of the piezoelectric layer, which bears interdigital transducers and includes acoustic structures.

37. An electronic component according to claim 31, in which the GDE layer and at least one piezoelectric layer are separated by an electrode layer.

38. An electronic component according to claim 31, wherein only one piezoelectric layer is provided that serves both as the excitation portion to excite the acoustic wave and as the tuning layer to mechanically warp the GDE layer.

39. An electronic component according to claim 31, in which the GDE layer is arranged between the excitation layer and the tuning portion.

40. An electronic component according to claim 31, wherein the GDE layer possesses electrically-conductive characteristics and replaces one of the electrodes.

41. An electronic component according to claim 31, in which the GDE layer and the tuning portion are arranged between two control voltage electrodes.

42. An electronic component according to claim 31, wherein the excitation portion is comprised of material selected from a group consisting of PZT, ZnO, AlN and GaN.

43. An electronic component according to claim 31, in which the multilayer structure is arranged on a substrate.

44. An electronic component according to claim 43, in which the carrier substrate comprises a multilayer structure.

45. An electronic component according to claim 43, in which the carrier substrate comprises a multilayer structure with at least one integrated element selected from a group consisting of passive elements, circuit elements and active circuit elements.

46. An electronic component according to claim 43, in which at least one discrete component selected from a group consisting of a passive component and an active component is arranged on the top side of the carrier substrate.

47. An electronic component according to claim 43, in which at least one chip component is arranged on the top side of the carrier substrate.

48. An electronic component according to claim 47, wherein the chip component is a SAW component.

49. An electronic component according to claim 43, in which at least one circuit element selected from a passive circuit element and an active circuit element integrated onto the carrier substrate forms at least one part of an adaptation circuit.

50. An electronic component according to claim 43, wherein at least one circuit element integrated onto the carrier substrate forms an element selected from a group consisting of at least one part of an antenna switch, a diode switch, a high-pass filter, a low-pass filter, a bandpass filter, a band elimination filter, a power amplifier, a diplexer, a duplexer, a coupler, a direction coupler, a balun, a mixer and a storage element.

51. An electronic component according to claim 43, which has at least one discrete circuit element selected from a passive circuit element and an active circuit element arranged on a top side of the carrier substrate forming a device selected from a group consisting of one part of an antenna switch, a diode switch, a high-pass filter, a low-pass filter, a bandpass filter, a band elimination filter, a power amplifier, a diplexer, a duplexer, a coupler, a direction coupler, a balun, a mixer and a storage element.

52. An electronic component according to claim 43, which includes at least one part of an adaptation circuit integrated onto the carrier substrate fashioned as one or more paths for later fine adaptation.

53. An electronic component according to claim 31, which has a carrier substrate that is a multilayer ceramic.

54. An electronic component according to claim 31, which includes a carrier substrate comprised of silicon.

55. An electronic component according to claim 31, which includes a carrier substrate comprised of an organic material selected from a plastic and a laminate.

56. An electronic component according to claim 31, which has a substrate and has one or more chip components and one or more discrete, passive or active circuit elements arranged on the top side of the carrier substrate to represent SMD elements.

57. An electronic component according to claim 31, which has a carrier substrate and at least one chip component and housing being arranged on the top side of the carrier substrate.

58. An electronic component according to claim 31, which has a carrier substrate with at least two chip components arranged on the top side of the carrier substrate contained in a common housing.

59. An electronic component according to claim 31, which has a carrier substrate and has at least two separately housed chip components on a top side of the carrier substrate.

60. An electronic component according to claim 31, wherein at least one of the HF electrodes and the control voltage electrodes comprises a plurality of layers.
